(19) United States
(12) Patent Application Publication
(10) Pub. No.: US 2006/0180829 A1
(43) Pub. Date: Aug. 17, 2006

(54) Tunneling gap diodes

(76) Inventor: Artemi Markovich Martsinovsky, St. Petersburg (RU)

Correspondence Address: BOREALIS TECHICAL LIMITED, 23545 NW SKYLINE BLVD, NORTH PLAINS, OR, 97133-9204, US

(21) Appl. No.: 11/392,182

(22) Filed: Mar. 29, 2006

Related U.S. Application Data
(60) Provisional application No. 60/666,654, filed on Mar. 29, 2005.

(30) Foreign Application Priority Data
Sep. 22, 2003 (GB) 0322116.5

(51) Int. Cl. H01L 29/88; H01L 21/331

(52) U.S. Cl. 257/104; 438/309

(57) ABSTRACT

The present invention discloses a tunneling diode having a band gap material as the collector. This increases the tunneling of electrons having greater energy than the Fermi level from emitter to collector, leading to an increase in the efficiency of heat pumping or power generation by the diode. In a further embodiment the collector comprises a semiconductor on which a layer of band gap material is deposited. This approach also reduces back tunneling of electrons from collector to emitter.

### CROSS-REFERENCE TO RELATED APPLICATIONS

This application is a Continuation in Part of patent application Ser. No. ______ (application number not yet known) filed Mar. 22, 2006, which is the U.S. national stage application of International Application PCT/US04/031221, filed Sep. 22, 2004, which international application was published on Apr. 7, 2005, as International Publication WO2005/031780 in the English language. The International Application claims the benefit of U.K. Application No. GB0322116.5, filed Sep. 22, 2003. This application also claims the benefit of U.S. Provisional Application No. 60/666,654, filed Mar. 29, 2005.

### BACKGROUND OF THE INVENTION

This invention relates to tunneling diodes and their application to heat pumping and power generation.

“Cool Chip” is hereby defined as a device that uses electrical power or energy to pump heat, thereby creating, maintaining, or degrading a thermal gradient. Cool Chips may accomplish this using thermionics, thermotunneling, or other methods as described in this application. It is understood that the present invention relates to Cool Chips.

“Gap Diode” is defined as any diode which employs a gap between the anode and the cathode, or the collector and emitter, and which causes or allows electrons to be transported between the two electrodes, across or through the gap. The gap may or may not have a vacuum between the two electrodes, though Gap Diodes specifically exclude bulk liquids or bulk solids in between the anode and cathode. The Gap Diode may be used for Cool Chips and for other diode applications. In the present invention thermotunneling is used as the means for producing cooling. The example of a diode heat pump is used henceforth as one model of all relevant diode applications. It is understood that all further references using the term ‘diode heat pump’ include all relevant diode applications using thermotunneling and/or thermionic emission.

Tunnel junctions of a new type that comprise Normal metal-Vacuum-Normal metal (NVN) have been disclosed [Avto Tavkhelidze, Larisa Koptonashvili, Zauri Berishvili, Givi Skhiladze, “Method for making diode device”, U.S. Pat. No. 6,417,060 B2]. A key advantage of these junctions is the use of a vacuum as the insulator. Consequently, there is formally zero heat conductivity between the electrodes, allowing the fabrication of tunnel junctions with extremely low thermal backflow.

Other groups have reported theoretical studies that seek to utilize the benefits of using a vacuum as an insulator. One group has considered utilizing tunnel emission through semiconductor resonant states [A. N. Korotkov and K. K. Likharev, “Possible cooling by resonant Fowler-Nordheim emission”, Appl. Phys. Lett. 75(16):2491-2493 (1999)]. This approach leads to a selective emission of electrons from the cathode and improves the efficiency of the device. Another group proposes cooling via electron field emission from diamond or III-nitride thin films deposited on metal or silicon substrates [P. H. Cutler, N. M. Miskovsky, N. Kumar and M. S. Chung, “New Results on Microelectronic Cooling Using the Inverse Nottingham Effect. Low temperature Operation and Efficiency”, Electrochemical Soc. Proc. Volume 2000-28, pp 99-111 (1999)]. A yet further theoretical study has considered how the effective work function for emission may be lowered by reducing the gap between the electrodes to a nanometer, and it is predicted that a material having a work function of ˜1.0 eV would show an effective work function of ˜0.4-0.3 eV or less under these conditions [Y. Hishinuma, T. H. Geballe, B. Y. Moyzhes, T. W. Kenny, “Refrigeration by combined tunneling and thermionic emission in vacuum: Use of nanometer scale design”, Appl. Phys. Lett. 78(17):2752-2754, (2001)]. Experimental work using a small nm-sized gap showed the expected lowering of the vacuum barrier between the electrodes, enabling emission from surfaces with work functions of ˜1 eV at room temperature [Y. Hishinuma, T. H. Geballe, B. Y. Moyzhes, T. W. Kenny, “Measurements of cooling by room-temperature thermionic emission across a nanometer gap”, Appl. Phys. Lett. 94(7) :4690-4696, (2003)]. Further theoretical work from this group has suggested that the need for materials with work functions near 1.0 eV (which is difficult to achieve in practice), may be circumvented by the use of a semiconductor layer on the emitter in combination with a strong electric field [Y. Hishinuma, T. H. Geballe, B. Y. Moyzhes, T. W. Kenny, “Vacuum thermionic refrigeration with a semiconductor heterojunction structure”, Appl. Phys. Lett. 81(22):4242-4244, (2002)].

It is well known that thermionic diodes offer the possibility of efficient cooling: every electron that leaves the emitter carries away energy WF+2 kT (where WF is the work function of the emitter electrode). However, for room temperature cooling effects, materials having work functions of the order of ˜0.3-0.35 eV are needed for the emitter, and such materials are not practically available.

For tunnel diodes having metal electrodes the situation is different. All the electrons can tunnel (though with different probability), whether they have an energy level above the Fermi level (E_{f}), or below. Those electrons which have energy E above the Fermi level, carry away energy E-Ef; those electrons which have E<Ef, return energy Ef-E to the emitter. As a result, the sum effect is significantly less than with thermionic diodes. Even if the work function is reduced to ˜0.3-0.35 eV by an applied bias voltage, common tunnel diodes with metal electrodes thus have two major drawbacks: (i) electrons below the Fermi level may tunnel; (ii) electrons may back tunnel from anode to cathode. As a result, high cooling power up to 10 W/cm² and more may be obtained, but at very low efficiency (˜1% or less) Thus approaches, such as those described by Korotkov and Likharev (1999) and by Hishinuma et al. (2002), which use selective emission from above Fermi level states, have relatively high efficiency. But even in these cases, the efficiency is far from Carnot one, and these methods, (especially the latter) impose additional technological difficulties for tunnel diode creation, which at the nm scale is extremely difficult.

### BRIEF SUMMARY OF THE INVENTION

From the foregoing, it may be appreciated that a need has arisen for an improved tunneling gap diode in which only electrons above the Fermi level tunnel from emitter to collector, and in which back tunneling, from collector to emitter, is suppressed.

The present invention discloses a tunneling diode having a band gap material as the collector, or having a metal electrode coated by a film of band gap material with a thickness greater than the mean distance of relaxation of tunneled emitter electrons (˜10 nm or more). This increases the tunneling of electrons having greater energy than the Fermi level from emitter to collector, leading to an increase in the efficiency of heat pumping or power generation by the diode. In the context of this invention, the term “band gap material” is defined as a crystal material having a filled zero temperature valence band and an empty conductive band. The band gap material may be a material such as a dielectric or semiconductor.

In a further embodiment, the tunneling diode may have the same or different band gap material as emitter, or a metal emitter, coated by the same or different band gap material. This not only increases the tunneling of electrons having greater energy than Fermi level from emitter to collector but also suppresses partially the back emission from anode to cathode, leading to an increase in the efficiency of heat pumping or power generation by the diode.

For these embodiments, the band gap material may be present as a layer of band gap material, or may be a hetero-structured band gap layer.

The present invention also comprises a method for promoting the tunneling of electrons having an energy level higher than the Fermi level from an emitter surface, comprising the step of positioning a collector comprising a band gap material at a distance within the tunneling range of the electrons.

The present invention also comprises a method for suppressing back tunneling of electrons from emitter to collector by using an emitter comprised of a band gap material.

The present invention also comprises a vacuum diode heat pump for heat pumping applications comprising the tunneling diode of the present invention.

The present invention also comprises an electrical power generator comprising the tunneling diode of the present invention.

### BRIEF DESCRIPTION OF THE SEVERAL VIEWS OF THE DRAWING

For a more complete explanation of the present invention and the technical advantages thereof, reference is now made to the following description and the accompanying drawings in which:

FIG. 1A and 1B show in diagrammatic form two embodiments of a tunnel diode of the present invention;

FIG. 2 shows in diagrammatic form various energy levels of a close-spaced tunnel diode of the present invention;

FIG. 3A and 3B show in diagrammatic form two embodiments of a tunnel diode device of the present invention for pumping heat or power generation;

FIG. 4 shows in diagrammatic form the dependence of two main parameters of the cooling device of the present invention (cool power Q and relation of cooling efficiency h to Carnot efficiency hc) in relation to the bias as various values of the energy difference between an anode Fermi level and a bottom of conductive band of a semiconductor;

FIG. 5 shows the diagram of FIG. 4 for another regime: T1=4K and T2=10K; and

FIG. 6 shows the same parameters Q (curves 1-5) and h/hc (curves 1′-5″) for the case T1=4K=const and increasing values of T2.

### DETAILED DESCRIPTION OF THE INVENTION

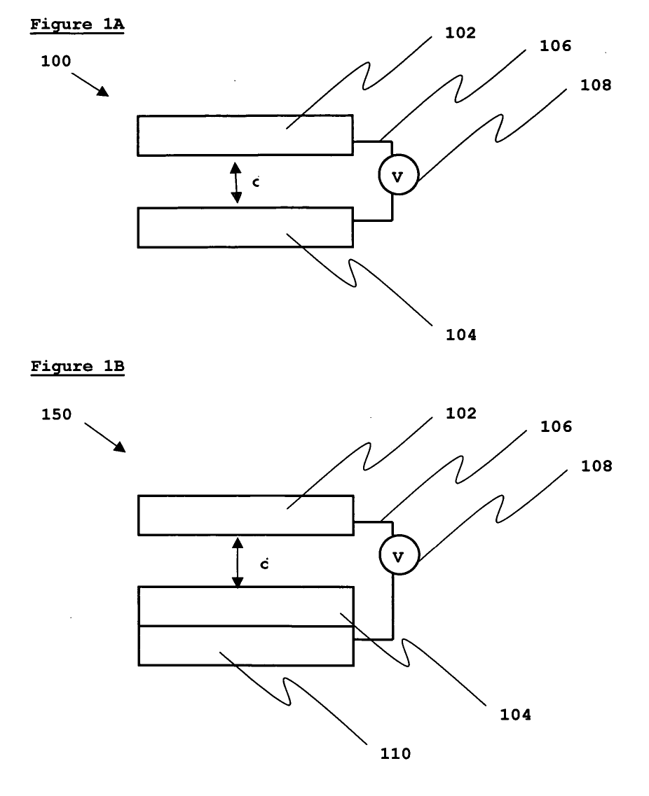

The embodiments of the present invention and its technical advantages are best understood by referring to FIGS. 1-6.

FIG. 1A shows in diagrammatic form a tunnel diode 100 comprising a metal emitter 102, a collector 104, an external circuit 106 and a voltage source, 108. The collector comprises a band gap material, which is to be understood in this present disclosure to indicate a material in which there is a forbidden region between a lower valence band and an upper conduction band. The band gap material may be a semiconductor, such as Ge, Si, GaAs or SiC. The band gap material may be a hetero-structured semiconductor, made from several thin layers of material with different band gaps. The layers can be anything from a few atoms in thickness right up to micrometre size and the materials used are typically gallium arsenide (GaAs) or aluminium gallium arsenide (AlGaAs). The band gap material may also be a material such as diamond or doped diamond. It also includes materials such as the alkali metal oxides or the alkaline earth oxides.

FIG. 1B discloses another embodiment of the present invention. A tunnel diode 120, such as tunnel diode 100 disclosed in FIG. 1A above comprising a metal emitter 102, a collector 104, an external circuit 106 and a voltage source, 108; has a band gap material 110 deposited as a layer on metal collector 104.

For the embodiments shown in FIG. 1A and 1B, the space d between the two electrodes is of the order of 1-20 nm, and is maintained at this distance by a housing (not shown). Preferably the space between the electrodes is evacuated, or filled with an inert gas at low pressure, such as argon.

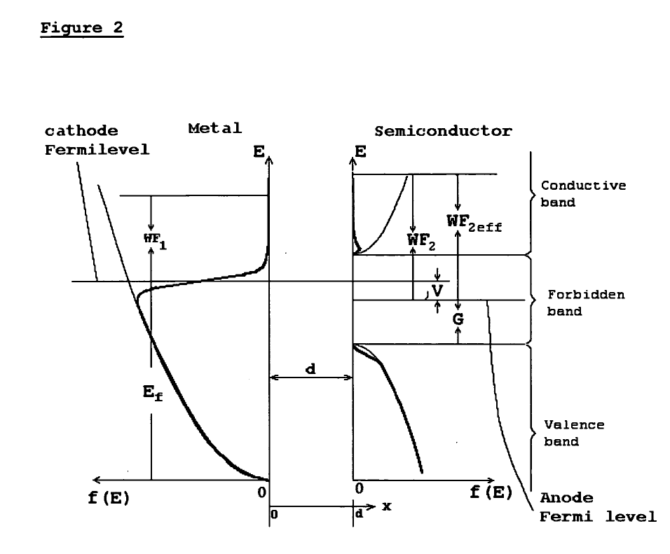

Without wishing to be bound by a particular doctrine, the operation of the tunnel diode of the present invention may be understood by referring to FIG. 2, which shows various energy levels for a metal cathode (or emitter) positioned a small distance d away from a semiconductor anode (or collector). Distance d is preferably of the order of 1-100 nm, most preferably 1-10 nm. The semiconductor shown in FIG. 2 is pure semiconductor. It is well known that the Fermi level of such a semiconductor lies near the center of forbidden band G.

The vertical axis in FIG. 2 represents potential energy, with zero signifying the bottom of the metal conductive band. The horizontal axis represents the electron and electron state density f(E) in the metal and in the semiconductor, and the distance x between electrodes. Electron density in the conducting band of the metal and in the conducting (upper) and valence (lower) bands of semiconductor is shown by the bold lines, and the thin lines represent the electron states density. The difference between Fermi levels of the electrodes, V, is the applied voltage (V bias).

WF₁ is the work function of the metal, WF₂ is the work function of the semiconductor, and G is the forbidden band. WF₂ is the “thermionic” work function, i.e. the energy interval between the Fermi level and the vacuum level; then WF_{2eff}=WF₂−G/2 is the energy interval between the bottom of the conductive band and the electron energy level in the vacuum.

If the forbidden band G of the semiconductor is not too large (for example, about 0.5-1 eV), thermal excitation of electrons from the valence band into the conductive band is sufficiently fast for electrical current transmission in the semiconductor (especially if it is a layer ˜10-15 nm “thin” for conductivity and “thick” for tunnel processes).

From FIG. 2 it can be seen that tunnel exchange by electrons between electrodes is possible only above or below the forbidden band, because the forbidden band does not have any permitted electron states. Since the probability for tunneling is much less for states below the forbidden band than for states above it, tunneling from the metal to below the semiconductor forbidden band can be neglected, and it is only tunneling from the metal to the conductive band that needs to be taken into account. This region has an energy level of G/2-V above the Fermi level of emitter.

What this means is that the use of a semiconductor collector prevents tunneling from emitter to collector for electrons which lie opposite the forbidden gap of semiconductor, i.e. just below Fermi level of emitter. Moreover, the use of a semiconductor with a gap of E₀ between the Fermi level and the bottom of the conductive band, tunneling from emitter for electrons with energy less than E₀ is prevented.

A further aspect of the invention is that the application of a voltage bias V between electrodes allows electrons with energies greater than E₀-V to tunnel. In other words, the tunnel diode of the present invention is equivalent to a thermionic diode with an “artificial” work function of E₀-V. The magnitude of the artificial work function can be adjusted for the operating conditions, especially for operating temperature, by the choice of E₀ and V.

Referring again to FIG. 2 it can be seen that the majority of electrons that tunnel will carry away from the emitter energy of not less than G/2-V. As discussed above, this potential threshold (G/2-V) is equivalent to the emitter work function in thermionic diodes, and can be adjusted to optimal low (for example, ˜0.4-0.3 eV for operation at temperatures ˜250-350K) value by applied voltage V. In effect this means that the tunnel diode of the present invention is as efficient as a thermionic diode for cooling, and that this level of cooling can be achieved in practice without resorting to exotic materials having low work functions. In fact, its “work function” can be chosen, and the cooling power and efficiency manipulated, by varying V and gap size d.

For semiconductors with a large E₀ (for example, E₀>1 eV), the tunnel current from the emitter will be too small at low V values of ˜0.1-0.2V. However at V values of 0.7-0.75V, the effective barrier will be optimum for room temperature cooling (0.3-0.4 eV). In other words, adjusting the bias level so that E₀-V=0.3-0.35 eV corresponds to optimum emitter WF of thermionic cool diode for chosen emitter and collector temperatures. Even if E₀ is in the range 3-4 eV, V can be set at 2.7-3.7V. Of course, such high biases values will give lower efficiency, but reasonable currents can be obtained at d=˜5 nm, compared to d=˜2 nm for ˜10 A/cm\hat{0}2 currents and a V ˜0.1 V for high efficiency cooling operation.

For a semiconductor, varying the electron donor concentration allows the position of the Fermi level to be moved from the centre of the forbidden gap to nearer the bottom of the conductive band. This means that a range of semiconductors may be used, including Ge (G=0.75 ev), Si (G=1.12 eV), GaAs (G=1.43) or SiC (G=2.4-3.4 eV), and the effective work function may be modified to any appropriate value, up to 0.1-0.01 eV or less. Alternatively a hetero-structure semiconductor may be utilized. For operation at temperatures below room range the semiconductor may be appropriately doped, since it is well-known that semiconductors with high doping by an electron donor dopant can have E₀ up to 0. At the higher temperature ranges, semiconductors with less dopant concentration and thus a higher E₀ may be used (for example, for room temperature operation, E₀˜0.3-0.6 eV).

Thus there is a wide range of semiconductor materials that may be used as the band gap material in the tunnel gap diode of the present invention for cooling applications. The two key design features are that (i) the band gap material used must have sufficient conductivity for working currents (1-100 A/cm2); and (ii) the band gap material should give low WF (˜1-1.2 eV) after Cs═O₂ treatment (or by treatment of other electropositive atoms such as other alkali metals, alkali-earth metals (Ba, Sr), la, Y, Sc etc., and other electronegative atoms (F and another halogens, S, etc).

For power generating applications the output voltage is small (˜0.1 V or less), and so E₀ should be less ˜0.2-0.4 eV for emitter temperatures 300-400K. But for higher temperatures (500-600-700K) the preferred value for so rises, and for 700-800K it can be ˜1 eV.

### EXAMPLE 1

In one embodiment, pure Ge is the semiconductor. It has G=0.75 eV, and G/2=0.375 eV, a little more than optimum WF for thermionic diode for Tc (temperature of emitter, cold electrode, hereafter referred to as T1)=300K (”0.33eV). Even at room temperature, Ge has electron concentration in conductive band ˜10¹³ cm⁻³, which is sufficient for electrical conductivity for thin layer. If it is assumed that electrodes are treated by Cs and O₂ and has WF1=WF2=1 eV, then the output parameters for cooling with d=2.5 nm, T1=300K, Th (temperature of collector, hot electrode, hereafter referred to as T2)=350K are given below:

| | | | | | | hcool/ |
|---|---|---|---|---|---|---|
| | | | | | | hcool |
| V, V | j, A/cm2 | Qc, W/cm2 | W, W/cm2 | COP | hcool | Carnot |
| 0.10 | 1.76 | 0.63 | 0.177 | 3.56 | 0.78 | 0.91 |
| 0.14 | 6.82 | 2.22 | 0.796 | 2.32 | 0.699 | 0.816 |
| 0.20 | 36.6 | 9.70 | 7.315 | 1.32 | 0.57 | 0.665 |

Here j is resulting diode current, Qc cooling power, W=j*V=spent power. Calculations were fulfilled with some simplifications as follows.

For elementary tunnel current from emitter, which is produced by electrons of the metal conductive band with energy interval E, E+dE and with energy Ex, Ex+dEx in direction normal to the emitted surface, we use expression:

$${dj}_{+} = q \frac{4 π m}{{h}^{3}} \frac{1}{1 + exp \frac{E - {E}_{f}}{{kT}_{1}}} ( 1 - \frac{1}{1 + exp \frac{E + V - {E}_{f}}{{kT}_{2}}} ) P ( {E}_{x} ) {dE}_{x} dE \qquad ( 1 )$$

where q and m is the charge and mass of electron, h and k—Plank and Boltzmann constants, T1 and T2—emitter and collector temperatures, Ef—Fermi energy of emitter, P(Eₓ)—tunnel probability for electrons with normal energy Eₓ. Tunnel probability was determined in BWK approximation:

$$P ( {E}_{x} ) = exp [ - \frac{4 π}{h} {\int }_{{x}_{1}}^{{x}_{2}} \sqrt{2 m ( V ( x ) q - {E}_{x} )} ⅆ x ] \qquad ( 2 )$$

where V(x) is potential distribution into the gap, x₁ and x₂ are the roots of equation:
V(x)=Eₓ (3)

For potential distribution equation (4) was used to take into account mirror image forces:

$$V ( x ) = \frac{WF}{q} - V \frac{x}{d} - \frac{q}{4 {πɛ}_{0}} [ \frac{1}{4 x} - \frac{1}{2} {\sum (}_{n = 1} \frac{nd}{{n}^{2} {d}^{2} - {x}^{2}} - \frac{1}{nd} ] \qquad ( 4 )$$

where ε₀ is vacuum permittivity, x—coordinate in direction normal to the surface. Assuming the replacement energy for electrons is E_{f}, this gives the following elementary heat flux generated by the by elementary tunnel current:

$${dQ}_{+} = q \frac{4 π m}{{h}^{3}} \frac{E - {E}_{f}}{1 + exp \frac{E - {E}_{f}}{{kT}_{1}}} ( 1 - \frac{1}{1 + exp \frac{E + V - {E}_{f}}{{kT}_{2}}} ) P ( {E}_{x} ) {dE}_{x} dE \qquad ( 5 )$$

The following analogous expressions were used for elementary tunnel current and heat flux from collector to emitter:

$$\begin{matrix}{dj}_{+} = q \frac{4 π m}{{h}^{3}} \frac{1}{1 + exp \frac{E + V - {E}_{f}}{{kT}_{2}}} ( 1 - \frac{1}{1 + exp \frac{E + {E}_{f}}{{kT}_{1}}} ) P ( {E}_{x} ) {dE}_{x} dE & ( 6 ) \\ {dQ}_{+} = q \frac{4 π m}{{h}^{3}} \frac{{E}_{f} - E}{1 + exp \frac{E + V - {E}_{f}}{{kT}_{2}}} ( 1 - \frac{1}{1 + exp \frac{E - {E}_{f}}{{kT}_{1}}} ) P ( {E}_{x} ) {dE}_{x} dE & ( 7 )\end{matrix}$$

Integrating of (1) and (5-7) with corresponds limits for E and Eₓ yields the relationship between current and heat flux between electrodes and to calculate parameters of a cooling device.

This shows that, for low biases, there is very high efficiency, but relatively low cool power. But with a small increase of V the cooling power increases by more than one order (to ˜10 W/cm²), whilst the efficiency falls by only a small amount (COP>1).

Note, by a small decrease of the gap (to 2 nm) the output parameters can be significantly improved:

| | | | | | | hcool/ |
|---|---|---|---|---|---|---|
| | | | | | | hcool |
| V, V | j, A/cm2 | Qc, W/cm2 | W, W/cm2 | COP | hcool | Carnot |
| 0.1 | 44.6 | 15.6 | 4.46 | 3.57 | 0.78 | 0.908 |

Importantly, these data show that it is possible to have a good cooling performance even for WF>1 eV at thinner gaps. For example, for WF=1.3 eV (a common value for anodes of standard thermionic converters), and a gap d=1.6 nm we have:

| | | | | | | hcool/ |
|---|---|---|---|---|---|---|
| | | | | | | hcool |
| V, V | j, A/cm2 | Qc, W/cm2 | W, W/cm2 | COP | hcool | Carnot |
| 0.12 | 19.3 | 6.13 | 2.32 | 2.646 | 0.726 | 0.847 |

Of course, it is possible to use other semiconductor materials, which can give still better performance, including specially formulated materials specific for these applications. Of course, for different cooling tasks different materials will be required. The use of a semiconductor collector is favorable for power producing too. For this purpose special materials are optimal.

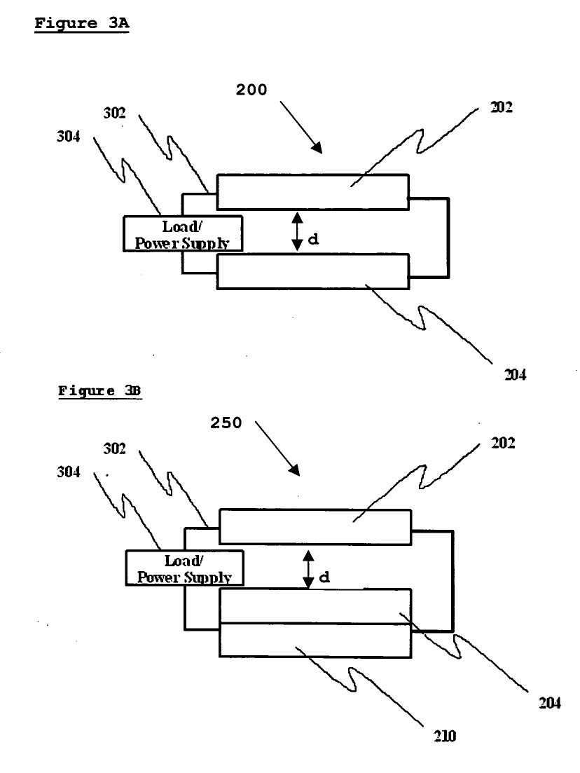

Referring now to FIG. 3A, which shows in diagrammatic form one embodiment of a tunnel diode device of the present invention 200. Tunnel diode device 200 comprises an emitter 202 and a collector 204 positioned facing each other with a distance d between them. In FIG. 3A, collector 204 is a semiconductor material.

FIG. 3B shows another embodiment of a tunnel diode device of the present invention 250, such as device 200 shown in FIG. 3A above. The embodiment shown in FIG. 3B similarly shows an emitter 202 and a collector 204 positioned facing each other with a distance d between them, but collector 204 additionally comprises a layer of a band gap material 210.

For a vacuum diode heat pump, tunnel diode devices 200 or 250 shown in FIGS. 3A and 3B above may be connected via an external circuit 302 to a power supply 304. Emitter 202 is in thermal contact with an object to be cooled (not shown), and collector 204 is in thermal contact with a heat sink (not shown).

For a heat to electricity converter, tunnel diode devices 200 or 250 shown in FIGS. 3A and 3B may be connected via an external circuit 302 to an electrical load 304. Emitter 202 is in thermal contact with a heat source (not shown), and collector 204 is in thermal contact with a heat sink (not shown).

### EXAMPLE 2

In a further embodiment, the tunnel diodes of the present invention are workable in the low (cryogenic) temperature region with relatively high efficiency, if the distance between Fermi level and the bottom of the conductive band (E₀) of the collector is sufficiently low.

Referring to FIG. 4, the dependence of two main parameters of cooled device, namely cool power Q and relation of cooling efficiency h to Carnot efficiency hc, are shown in relation to the bias at various values of parameter G (energy difference between an anode Fermi level and a bottom of conductive band of semiconductor). Regime is: d=2.5 nm (all calculations have done for this gap, the currents are not too big for it), T1=20K (liquid H₂), T2=40K. G values are: 1-0.007 ev, 2-0.01, 3-0.02, 4-0.03, 5-0.04, 6-0.05. The green line is the cool power, and the red line is h/hc. It is seen firstly, that parameters are more than good in spite of such a low T1. Note, for common metal—metal case cooling is stopped at parameters T1=170K, T2=200K (!). We have cooling ˜10 mW/cm2 (at so low temperatures it is very much) at very high efficiency h/hc ˜0.5. It is seen also, that low limit value of G is for this case ˜0.007 eV, for still small G cooling disappears. Optimum G value is near 0.02 mV. For this regime for Q=5 mW/cm2 h/hc=0.55. Because hc=0,5 here, h =27%! For Q=10 mW, h/hc=0.45. At larger values of G efficiency decreases, but due to a corresponding increase of the bias (curves shift to the right) this decreasing is very gradual. It is illustration of relatively small influence of the G value on the cool diode performance, which is very important for the practice.

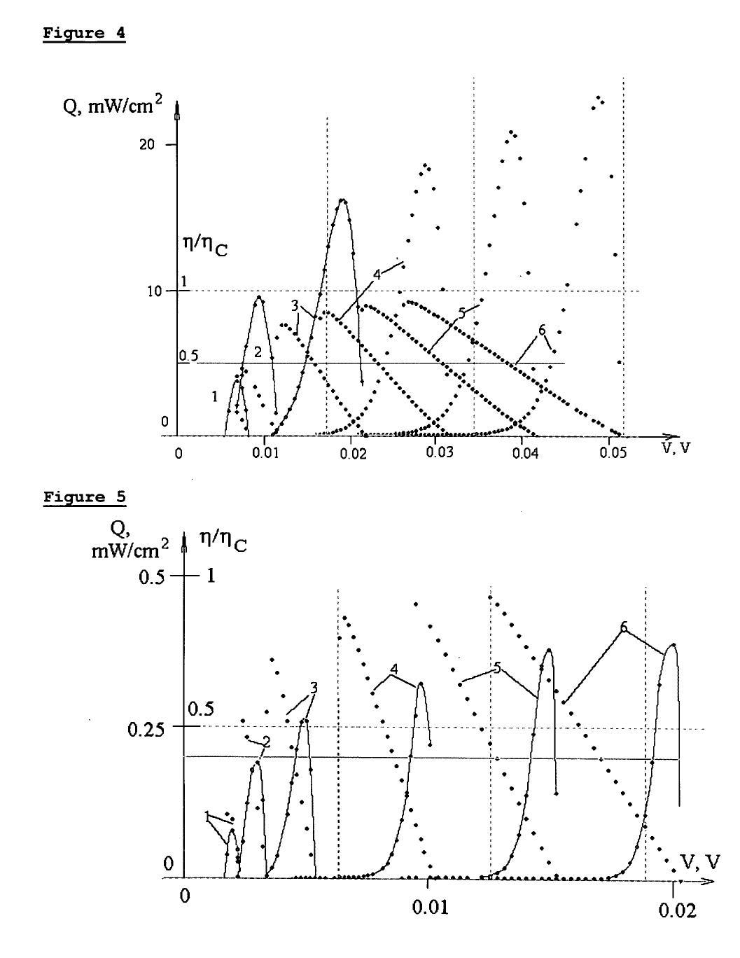

Referring to FIG. 5, which shows the same picture for another regime—T1=4K and T2=10K. The low limit G is here 0.002 eV, optimum value is near 0.003 eV—it is reasonable because T1 is much lower of course, in this case cooling is on the order less, tenth of mW, but for He temperature it is fantastic! For optimum G=0.003 eV for Q=0.2 mW/cm2 h/hc=0.4.

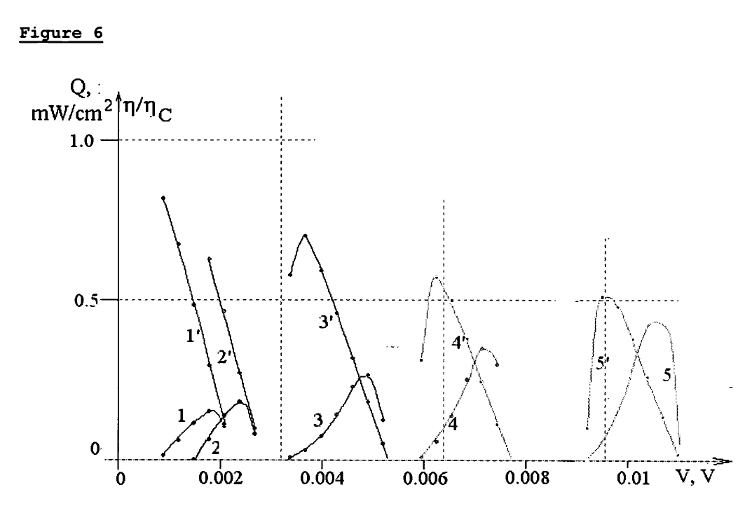

Referring to FIG. 6, which shows the same parameters Q (curves 1-5) and h/hc (curves 1′-5″) for the case T1=4K=const and increasing values of T2. T2, K: 1-6; 2-8; 3-4-15; 5-20. For the every T2 value optimum value G was determined (approximately), and curves are for this optimum values:

| T2 | G |
|---|---|
| 6 | 0.002 |
| 8 | 0.003 |
| 10 | 0.0055 |
| 15 | 0.0075 |
| 20 | 0.0115 |

It is seen from FIG. 6, that the increase of ΔT (ie. T2-T1) at T1=constant even for Helium temperatures and doesn't lead to a significant decrease in efficiency. Adjusting the correspondent G value and increasing the biases compensate for the effects of the rise in anode temperature. Furthermore, T2=40K at T1=4K, and the result is the same as h/hc changes slowly. Of course, h decreases significantly—but this is only due to T1/T2 decreasing.

FIG. 6 shows also, that we can have, in principle, a big temperature difference at the diode without a significant decrease of efficiency and have, for example, T1=4K and T2=78K (liquid Nitrogen), or even more. But from a technological point of view it is far from optimum construction. Large values of ΔT, especially at low temperatures, will lead to big thermal losses due to conductivity, and to high strength in the Cool Chip construction. It is more suitable to use a roll of Chips, when every of them is developed for its own temperature range. The slight sensitivity of the cool diodes to G lightens an assembling such composite cooler (like thermoelectrical coolers).

Preferred values of E₀≈(10-20)kT1. For example, for temperature range 4-20K favorable values of E₀ is 0.002-0.1 eV. In this case we can get cooling ˜ mW and more at high efficiency—up to 50% of Carnot one and more (see FIGS. 4 and 5). Semiconductor materials with such values of E₀ can be heavy doped n-type semiconductors with fine electron donors. Such coolers could find extra wide applications practically in all branch of today industry.

Devices made according to the present invention may be used in diode devices, vacuum diode devices, heat pumps, and the like. For example, heat pipes based on this invention have specific power and efficiency commensurate with, or better than, common compressor refrigerators employing evaporated heat carrier, and specific weight and volume commensurate with (or better than) thermoelectrical (semiconductor) ones. Because production of such heat pipes can be based on nanotechnology and micromachining, they should be sufficiently cheap to manufacture. As a result, they can be used with great economical effect in practically all areas of refrigerating: domestic and industry refrigerator (especially freight and ship refrigerators), air-conditioning, cooling of technical and especially electron devices, including computer devices (processors first of all), sensors (especially infrared ones), refrigerators for aerospace applications, etc. In prospect, they should replace most, if not all, parts of existing refrigerators. The combination of high efficiency and small specific weight and volume, with the ability to work significantly below room temperatures, promises numerous new, and unpredictable applications.

While this invention has been described with reference to numerous embodiments, it is to be understood that this description is not intended to be construed in a limiting sense. Various modifications and combinations of the illustrative embodiments will be apparent to persons skilled in the art upon reference to this description. It is to be further understood, therefore, that numerous changes in the details of the embodiments of the present invention and additional embodiments of the present invention will be apparent to, and may be made by, persons of ordinary skill in the art having reference to this description.

1. A tunneling diode comprising:
an emitter electrode;
a collector electrode, said collector electrode substantially facing said emitter electrode;
an electrical circuit connecting said emitter and said collector electrode; and
a source of power connected to said electrical circuit;
whereby said collector electrode comprises a band gap material, said band gap material being a crystal material having filled zero temperature valence band and empty conductive band.

2. The tunneling diode of claim 1, additionally comprising an emitter coated with a layer of a band gap material.

3. The tunneling diode of claim 1, wherein said collector electrode comprises a layer of band gap material deposited on a metal collector.

4. The tunneling diode of claim 3, wherein said layer of material has a thickness greater than the mean distance of relaxation of electrons tunneling from said emitter electrode.

5. The tunneling diode of claim 1, wherein said band gap material is selected from the group consisting of: a semiconductor, a hetero-structured semiconductor, a dielectric, a diamond material, an alkali metal oxide and an alkaline earth oxide.

6. The tunneling diode of claim 1, wherein said band gap material is selected from the group consisting of: Ge, Si, GaAs, SiC and AlGaAs.

7. The tunneling diode of claim 1, wherein said emitter and said collector electrodes are separated by a gap in the range 1-100 nm.

8. The tunneling diode of claim 1, wherein said emitter and said collector electrodes are separated by a gap in the range 1-10 nm.

9. The tunneling diode of claim 1, wherein a gap between said emitter and said collector electrodes is evacuated.

10. The tunneling diode of claim 1, wherein said tunneling diode comprises a cryogenic cooler.

11. A vacuum diode heat pump comprising said tunneling diode of claim 1, wherein said emitter electrode is in thermal contact with an object to be cooled and said collector electrode is in thermal contact with a heat sink.

12. A heat to electricity converter comprising said tunneling diode of claim 1, wherein said emitter electrode is in thermal contact with a heat source and said collector electrode is in thermal contact with a heat sink.

13. A method for promoting the tunneling of electrons having an energy level higher than the Fermi level comprising the steps of:
a) providing an emitter electrode;
b) providing a collector electrode, whereby said collector electrode comprises a band gap material, said band gap material being a crystal material having filled zero temperature valence band and empty conductive band;
c) positioning said collector electrode facing said emitter electrode at a distance within the tunneling range of the electrons;
d) connecting said emitter and said collector electrodes to an electrical circuit;
e) providing a source of power connected to said electrical circuit.

14. The method of claim 13 further including a method for suppressing back tunneling of electrons whereby said step of providing an emitter electrode comprises the step of providing an emitter electrode, said emitter comprising a band gap material.

15. The method of claim 13, wherein said step c) comprises the step of providing a collector electrode, whereby said collector electrode comprises a layer of band gap material deposited on a metal collector, said band gap material being a crystal material having filled zero temperature valence band and empty conductive band.
